(19) United States
(12) Patent Application Publication
(10) Pub. No.: US 2025/0116738 A1
(43) Pub. Date: Apr. 10, 2025

(54) Stimulation-Optimized Gradient Coil

(71) Applicant: Siemens Healthineers AG, Forchheim (DE)

(72) Inventors: Andreas Krug, Fürth (DE); Sascha Fath, Erlangen (DE); Simon Bauer, Eggolsheim (DE)

(73) Assignee: Siemens Healthineers AG, Forchheim (DE)

(21) Appl. No.: 18/907,814

(22) Filed: Oct. 7, 2024

(30) Foreign Application Priority Data
Oct. 9, 2023 (EP) 23202399.4

(51) Int. Cl. G01R 33/385

(52) U.S. Cl. CPC G01R 33/385

(57) ABSTRACT

A gradient coil arrangement of an MRI system is described that defines a first and at least one second axis in different spatial directions. Disposed in each spatial direction is at least one gradient coil which generates a magnetic gradient field along the respective axis. The magnetic gradient fields each have a maximum field region which corresponds to a region in which the field strength attains a predetermined percentage of the maximum strength. The gradient coil of the first axis is configured such that the overlap of its maximum field region with that of the at least one second axis is less than a limit value.

### CROSS-REFERENCE TO RELATED APPLICATIONS

The present application claims priority to and the benefit of European patent application no. EP 23202399.4, filed on Oct. 9, 2023, the contents of which are incorporated herein by reference in their entirety.

### TECHNICAL FIELD

The present disclosure relates to the field of medical imaging and, in particular, to the design of gradient coil arrangements for magnetic resonance imaging systems.

### BACKGROUND

Magnetic resonance imaging (MRI) is a non-invasive imaging technique widely used for diagnosing a variety of diseases and conditions. MRI devices expose patients to time-dependent magnetic gradient fields, which, however, can generate electric fields within the patient's body. These electric fields can cause peripheral nerve stimulation (PNS), potentially even stimulating the heart in strong field situations, which is undesirable. This makes it necessary to limit the amplitudes and rise times of the gradient fields, but this limits the overall performance of the gradient system.

It has been found that the stimulation thresholds, i.e. the amplitudes/rise times at which stimulation can occur, largely depend on the configuration of the gradient coils that generate the gradient fields.

Existing solutions for optimizing the stimulation performance of gradient coils focus on optimizing the stimulation effect of individual gradient coils. To increase the threshold values, these solutions either increase the inductance of the coil or impair its linearity. However, these methods often result in power losses that can reduce the effectiveness and accuracy of the MRI scan.

### SUMMARY

There is therefore a need for improved solutions for configuring and optimizing gradient coils in MRI devices to mitigate the problem of peripheral nerve stimulation. This object is achieved by the embodiments as described herein, including the independent claims.

The following describes techniques relating to the claimed gradient coil arrangements and the claimed medical imaging systems (e.g. MRI systems). Features, advantages, or alternative exemplary embodiments can be assigned to the respective other categories, and vice versa. In other words, the claims for medical imaging systems can be improved by features described and/or claimed in the context of the gradient coil arrangement, and vice versa.

It is understood that the disclosed techniques described in connection with MRI systems can be used in coil arrangements of various other imaging methods in which magnetic fields are generated by a plurality of coils of a coil arrangement.

A coil arrangement, e.g. a gradient coil arrangement, is described below which can be disposed in a medical imaging system, for example, a magnetic resonance imaging (MRI) system.

The gradient coil arrangement defines a first axis and at least one second axis in different spatial directions. For each of the different spatial directions, the gradient coil arrangement has at least one coil, in other words a gradient coil, which is configured to generate a magnetic field, e.g. a magnetic gradient field, in the respective spatial direction, i.e. along the respective axis in that spatial direction. For example, a first (gradient) coil can generate a magnetic (gradient) field along the first axis (i.e. in the first spatial direction). The same applies to the second (gradient) coil and, optionally, further gradient coils in other spatial directions.

In various examples described here, the first axis includes a Z-axis of an MRI system along which an examination subject is aligned in the MRI system. In different examples, the at least one second axis can include the X-axis or Y-axis of the MRI system. However, it would also be conceivable for the first axis to include one of the X- or Y-axes of the MRI system and to be optimized relative to one or both of the other coils according to the techniques described.

The at least one second axis can include a second and a third axis, such that the gradient coil arrangement has a first, a second, and a third axis in different spatial directions. In various examples described here, the first axis can include the Z-axis of the MRI system, the second axis the Y-axis, and the third axis the X-axis.

The at least one gradient coil for each spatial direction, i.e. each axis, is designed such that its magnetic gradient field has a maximum field region corresponding to a spatial region where the field strength of the magnetic gradient field attains at least a predetermined percentage of the maximum field strength of the magnetic gradient field of the coil. In this region, the magnitude of the generated field (i.e. consisting of all three spatial components) reaches a maximum. In other words, a maximum field region can contain a field maximum, i.e. a field magnitude maximum, corresponding to the maximum magnetic field strength of the magnetic gradient field.

In some examples, the field strengths may relate to a region inside the coils where the respective magnetic gradient field is generated. The field strengths may relate to the region within the Z-coil where an examination subject can be located. The field strengths may relate to specific points where all three spatial components (generated by the coils in different spatial directions, e.g. X-, Y-, and Z-directions) combine into a resulting field strength acting on a patient. In other words, there can be a superposition of the field components whose maximum field strength can be reduced by the described techniques.

The field strengths, the maximum field region, e.g. the field maximum, of a coil may refer to the entire field generated by the respective coil. The field strengths, the maximum field regions, as well as the field maxima, may refer to a (partial) region, for example an area outside the isocenter, and/or including the isocenter and/or field-of-view for an MRI system, for example a region where an examination subject may be positioned within the gradient coil arrangement.

The design of the gradient coil in the first spatial direction, for example the Z-gradient coil, can be optimized with respect to the gradient coil of the at least one second axis. In some examples, the design of the Z-gradient coil can be optimized with respect to the X- and/or Y-axis.

The gradient coil of the first axis is configured such that a spatial intersection, in other words an overlap or region of spatial intersection, of its maximum field region with the maximum field region of the magnetic gradient field in the direction of the at least one second axis is less than a limit value. This criterion can also include the situation that, in some examples, the maximum field regions of the coils do not intersect or overlap.

In some embodiments, the design of the gradient coil in the first spatial direction, for example the Z-gradient coil, can be optimized with respect to the gradient coils of the second axis (Y-axis) and third axis (X-axis).

The gradient coil of the first axis can be configured such that a spatial overlap of its maximum field region with a combined maximum field region of the gradient coils of the second and third axes, resulting from a combination (superposition) of the magnetic gradient fields in the direction of the second and third axes, is smaller than a limit value.

It should be understood that the techniques described are not limited to optimizing the Z-gradient coil, but can also be used for the design of any other gradient coil. For example, it is also conceivable for any one of the X-, Y-, and Z-axis gradient coils to be optimized with respect to any other of the X-, Y-, and Z-axis gradient coils, or with respect to a combination of these gradient coils, according to the techniques described.

In other words, the configuration of the gradient coil of the first axis is such that its maximum field region either interacts only minimally, i.e. below a threshold value, or does not interact at all with the maximum field region of the magnetic gradient field in the direction of the at least one second axis. The configuration of the gradient coil of the first axis ensures that the maximum field regions of the first and the at least one second axis either overlap only minimally or not at all, i.e. that superposition of their maximum field regions is minimized or even eliminated completely.

Thus, instead of optimizing individual axes of the gradient coil, the overall stimulation effect of the coils of some or all of the spatial directions is taken into account. By shifting the position of the field (magnitude) maxima of the individual gradient fields, the stimulating effect on the patient's body is reduced. This allows for safer use of MRI scanners, e.g. with regard to the risk of peripheral nerve stimulation (PNS) and cardiac stimulation. As a result, the performance of the gradient system can be increased without exceeding the stimulation thresholds. Compared to previous solutions, where an increase in coil inductance or a deterioration in linearity was accepted, the described techniques enable stimulation performance to be improved without negatively affecting these parameters.

The gradient coil arrangement can be configured such that the predetermined percentage amounts to any suitable proportion, such as e.g. 90%, which can define the maximum field region. Alternatively, and as other examples, the predetermined percentage can amount to 80%, or 70%. This allows flexible adaptation of the gradient coil arrangement to the specific requirements of the MRI system and the patients to be examined. As further examples, the predetermined percentage can also amount to 60%, or 50%, or 40%, or even 30%, etc.

The limit value, which can define the size of the overlap, can involve an absolute value which can be determined using the maximum field regions of the gradient coils. For example, the limit value can correspond to a percentage of one of the maximum field regions or of the combined maximum field region. In other words, the limit value can be specified as the maximum value of the spatial overlap region that limits the size of the spatial overlap. For example, the limit value can be selected such that the spatial overlap region is less than any suitable proportion (e.g. 5%) of the maximum field region of the magnetic gradient field in the direction of the first axis, or of the maximum field region of the magnetic gradient field in the direction of the second or third axis, or of the combined maximum field region of the gradient fields along the second and third axis. As additional examples, the limit value can also be selected so that the percentage can amount to e.g. 10%, or 20%, or 30%, or 40%, or 50%, or 60%, etc., instead of 5%.

By limiting the spatial overlap of the maximum field regions, any undesirable superposition of the field maxima and therefore stimulation of the patient by the gradient fields can be avoided. For example, the limit value can thus determine the extent to which the maximum field regions, in other words field maxima, of the individual gradient fields are allowed to overlap or intersect, thereby creating spatial regions in which, due to superposition, i.e. summation of the magnitude of the field strengths, particularly high cumulative maximum field strengths may act on an examination subject.

The gradient coil of the first axis can be designed as a whole-body coil and as a Z-gradient coil. This enables the magnetic gradient field to be generated evenly and efficiently over the patient's entire body.

The gradient coil of the first axis can be configured such that its field effect maximum is shifted relative to the maximum of the combined field effects of the X- and Y-axes. This can be achieved, for example, by shifting the position of the field maximum, or the maximum field region, of the magnetic field strength of the gradient field of the first gradient coil along the first axis (for example the Z-axis), as described in more detail below.

The field maximum and/or the maximum field region of the gradient coil of the first axis can be arranged at a spatial distance (along the first axis) from the field maximum and/or maximum field region of the gradient coils of the second and/or third axis.

By shifting the location of the maximum field region of the gradient coil of the first axis relative to the maximum field regions of the second and/or third axis, or the combined maximum field region of the second and third axis, better control over the spatial location of the maxima of the magnetic gradient fields can be achieved. By spatially shifting the maximum field regions relative to each other, the sum of all the field strengths of the magnetic gradient fields generated by the gradient coils and acting on an examination subject, e.g. the superpositioned magnetic fields in a spatial overlap region, can be below a predetermined limit value. The spatial displacement can provide a safer and more patient-friendly MRI examination by minimizing the effect of strong magnetic fields on the body without compromising coil quality.

This can be achieved by various optimized configurations in the design of the field conductors of the first coil. For example, by optimizing the field conductor distribution along the longitudinal axis of the coil, the field maximum can be shifted along the longitudinal axis of the coil.

In various examples, the gradient coil of the first axis can be configured such that it has a reduced field conductor density or primary conductor density, e.g. no field conductor or primary conductor, along the first axis in the area of the maximum field region generated by the gradient coil of the at least one second axis.

In some examples, a projection of the maximum field region of the at least one second axis, or of the second and/or third axis, or of the combined maximum field region of the second and third axis, onto the first axis can define an axis section of the first axis.

In the axis section, the design of the field conductor/primary conductor can be modified in relation to a comparison region, for example an adjacent reference axis section of the same width along the first coil axis, in order to shift the position of the maximum field along the coil axis.

For example, there may be fewer turns in this section of the axis, resulting in a reduced field conductor density which can be at most any suitable proportion such as e.g. 5%, 10%, 20%, 30%, or 40%, etc., compared to the comparison axis section.

No field conductor or primary conductor of the first coil can be present in a radial region corresponding to this axis section, i.e. radially outside this section of the axis.

This allows a targeted reduction in the magnitude of the field strength of the resulting magnetic gradient field in the region of the field maxima of the second and/or third axis, and thus a reduction in the stimulation of the patient. It should be understood that other design modifications that cause the field maximum to be shifted along the coil axis may also be possible.

The gradient coil of the first axis can be configured such that the primary conductors are multilayered in a region along the first axis outside the axis section of the maximum field region of the gradient coils of the at least one second axis, the second axis or the third, or the combined maximum field region of the second and third axis, e.g. in one or both immediately adjacent regions along the first axis. In other words, in one or both regions (coil axis sections) directly adjacent to the free/reduced region in the axial direction (of the first coil), the primary conductors can be multilayered in the radial direction. For example, the primary conductors can be designed with two or three layers. This ensures efficient generation of the magnetic gradient field and a reduction in stimulation of the patient. The primary conductors can generate the magnetic gradient field of the coil.

The gradient coil of the first axis can be configured such that secondary conductors are disposed in the region of reduced field conductor density or without field conductors, i.e. in a region along the first axis within a radial region corresponding to the axial section of the maximum field region of the gradient coils of the at least one second axis, the second axis or the third axis, or the combined maximum field region of the second and third axis. This provides targeted shielding of the field strength of the magnetic gradient field. The secondary conductors cannot contribute to the generation of the magnetic gradient field. The secondary conductors can shield the magnetic gradient field of the second gradient coil toward the outside of the coil.

The gradient field of the gradient coil of the first axis can be rotationally symmetrical with respect to its longitudinal axis, e.g. a Z-axis of the MRI system. This can apply e.g. in a linearity region or in a predetermined area around the isocenter or center of the coil. This ensures uniform and efficient generation of the magnetic gradient field.

The gradient coil of the first axis can be mirror symmetrical with respect to a plane through the isocenter of the gradient coil arrangement. This ensures uniform and efficient generation of the magnetic gradient field.

Accordingly, a medical imaging system, e.g. an MRI device or MRI system, is provided, comprising a gradient coil arrangement according to the present disclosure.

Although the features described in the above summary and the following detailed description are described in the context of specific examples, it is to be understood that the features may be used not only in the respective combinations, but may also be used in isolation or in any combinations, and features from various examples of the medical imaging systems and coil arrangements may be combined and thus correlate with each other, unless expressly stated otherwise.

Thus, the above summary is intended to provide only a brief overview of some features of some exemplary embodiments and implementations and is not to be understood in a limiting sense. Other embodiments may include features other than those described above.

### BRIEF DESCRIPTION OF THE DRAWINGS

The disclosure will now be explained in more detail using exemplary embodiments and with reference to the accompanying drawings.

In the figures, identical reference characters denote identical or similar elements. The figures are schematic representations of various exemplary embodiments of the disclosure, wherein the elements shown in the figures are not necessarily to scale. Rather, the various elements shown in the figures are depicted such that their function and general purpose can be understood by a person skilled in the art.

FIG. 1 illustrates an example magnetic resonance system according to some exemplary embodiments;

FIG. 2 illustrates a conventional gradient coil;

FIG. 3 illustrates the field distribution of the conventional gradient coil from FIG. 2;

FIG. 4 illustrates the magnetic field strength distribution of the superimposed field strengths of all the gradient coils of a conventional gradient coil arrangement using the gradient coil from FIG. 2;

FIG. 5 illustrates an example optimized gradient coil according to some exemplary embodiments;

FIG. 6 illustrates an example comparison of the field maxima of the gradient coils from FIGS. 2 and 5, according to some exemplary embodiments;

FIG. 7 illustrates an example magnetic field strength distribution of the superimposed gradient fields of the gradient coil arrangement from FIG. 3 using the optimized gradient coil from FIG. 5, according to some exemplary embodiments.

### DETAILED DESCRIPTION OF THE DISCLOSURE

The features, characteristics, and advantages of the present disclosure described above and the manner in which they are achieved will become clearer and more readily understandable in connection with the following description of exemplary embodiments, which will be explained in more detail in connection with the figures.

It should be noted that the description of the exemplary embodiments is not to be understood in a limiting sense. The scope of the disclosure is not intended to be limited by the exemplary embodiments described below or by the figures, which are for illustrative purposes only.

Various techniques for gradient coil arrangements, e.g. for reducing the maximum field effect on examination subjects, which can occur as a result of superposition of the individual gradient fields, will now be described in more detail.

When operating magnetic resonance imaging (MRI) scanners, patients, or examination subjects are exposed to time-varying magnetic fields (gradient fields). These gradient fields are generated by the gradient coils of the MRI scanner and are used to perform spatial encoding of the measurement. These time-varying fields induce electric fields in the patient's body, which can stimulate the nerves (“peripheral nerve stimulation”, PNS). With stronger gradient fields, not only the nerves but also the heart muscle may be stimulated (cardiac stimulation). Both PNS and cardiac stimulation are generally undesirable and, in the case of cardiac stimulation, even potentially dangerous.

Therefore, the amplitudes and/or rise times of the gradient fields must be limited accordingly in order to avoid PNS and cardiac stimulation. This limits the achievable imaging performance of the gradient system. The stimulation threshold, i.e. the amplitudes and rise times above which stimulation can occur, depend on the design of the gradient coil that generates the gradient field. Gradient coils with a higher spatial encoding accuracy (field linearity) typically have lower stimulation thresholds than gradient coils with poorer linearity. The higher the potential gradient strength a coil can generate, the more it may need to be limited due to PNS or cardiac stimulation.

The performance of conventional gradient coils is limited by an appropriately parameterized stimulation monitor. This ensures that only a small proportion of patients actually experience PNS during operation. The limits of the monitor are selected such that cardiac stimulation is eliminated in any event.

In order to increase the stimulation thresholds, dedicated systems (e.g. head gradient coils) can be used, whereby the patient is not at the point of maximum field exposure or the conductor paths are positioned such that little stimulation occurs.

Previous proposals for optimizing the stimulation performance of gradient coils usually only consider the stimulation effect of the individual axes. In order to increase the thresholds, an increase in the inductance of the coil or a deterioration in linearity is accepted. In addition, stimulation-optimized designs that explicitly minimize nerve stimulation in the design process can only be used to a limited extent for whole-body coils or result in significant losses in gradient performance.

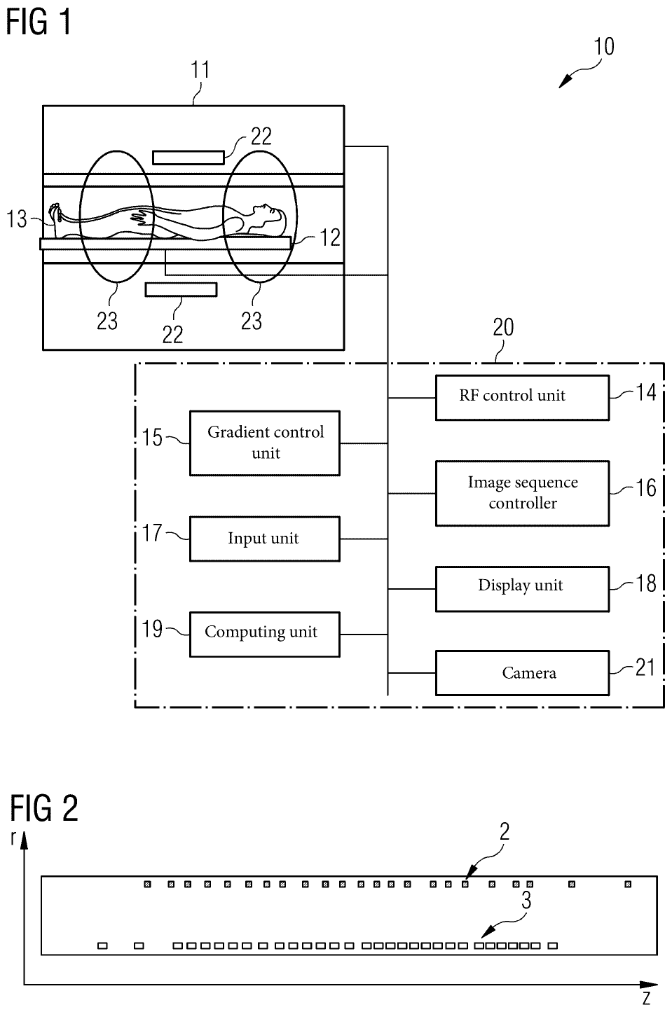

FIG. 1 illustrates a magnetic resonance system 10 according to exemplary embodiments of the disclosure.

As shown in FIG. 1, a magnetic resonance system 10 is presented with which, as will be explained below, a patient can be monitored. The magnetic resonance system 10 has a magnet 11 for generating a polarization field B0, wherein an examination subject 13 recumbently positioned on a table 12 is moved into the magnet 11 in order to acquire spatially encoded magnetic resonance signals, i.e. MR data, from the examination subject or patient 13. The gradient coils used for signal acquisition, e.g. gradient coils in the X- and Y-direction 22 and in the Z-direction (whole-body coil) 23 or local coils are shown schematically. By applying radiofrequency pulses and switching magnetic field gradients, the magnetization generated by the polarization field B0 can be deflected from the equilibrium position and spatially encoded, and the resulting magnetization is detected by the receiving coils. How MR images can be generated by the application of the RF pulses and switching of magnetic field gradients in various combinations and sequences will be generally well-known to a person skilled in the art and will not be explained in detail here.

In addition, the magnetic resonance system 10 has a control unit 20, which can be used to control the magnetic resonance system 10. The controller 20 has a gradient control unit 15 for controlling and switching the necessary magnetic field gradients. An RF control unit 14 is provided for controlling and generating the RF pulses for deflecting the magnetization. An image sequence controller 16 controls the sequence of the magnetic field gradients and RF pulses and thus indirectly the gradient control unit 15 and the RF control unit 14. An operator can control the magnetic resonance system 10 via an input unit 17, and MR images and other information required for control purposes can be displayed on a display 18. A computing unit 19 comprising at least one processor unit (not shown) is provided for controlling the various units in the control unit 20 and for performing computing operations. In addition, a camera 21 is provided with which images of the patient 13 can be captured. The computing unit 19 is configured to calculate the MR images from the acquired MR signals and to determine a movement of the patient 13 and the degree of movement on the basis of the images obtained. The degree of movement is then shown on the display 18 using a symbol (e.g. a head symbol).

For MRI measurements, pulses are generally not played out on individual gradient axes, but on combinations of different axes. The stimulation effect results from the superposition of the contributions of the individual axes. It is often only this superposition that results in stimulation, while the individual axes do not stimulate individually.

The aim is therefore not to optimize the individual axes, but to reduce the overall stimulation effect of the gradient coil. This results from the sum of all the field components of the three axes, i.e. the field components of the magnetic gradient fields of the X-, Y- and Z-axes.

In accordance with IEC 60601-2-33, the maximum value of the sum of the field contributions on a cylinder surface in the system core (radius 20 cm) is deemed to be a measure of the stimulation effect. The maximum of the sum of the X-, Y- and Z-components of all 3 axes is calculated at each axial position and plotted as a function of the axial position. As this maximum can be located at different axial positions on different circumferential positions, this results in curves as shown in the example.

The maximum of this curve is a measure of the stimulation effect of the entire coil. If the maxima of the individual axis contributions are close to each other, the maximum is increased. If the maxima are shifted axially, the cumulative effect decreases.

The aim is to generate the field effect of the individual axes at different Z-positions so that the “field effect” of the overall coil arrangement is limited. Since the transverse coils (X- and Y-gradient coils) are similar for given coil requirements, for them such a shift is more difficult to achieve compared to the modification of the Z-gradient coil. Therefore, the design of the Z-gradient coil is selected here such that its maximum is shifted in the direction of the longitudinal axis of the Z-gradient coil compared to the maxima in the X- and Y-directions.

FIG. 2 shows a cross-section along the longitudinal axis of a conventional gradient coil.

The gradient coil 1 has a conventional configuration with primary conductors 3 and secondary conductors 2 in a coaxial arrangement around a longitudinal axis which can be parallel to the Z-axis or coincide with the Z-axis of an MRI system. For example, the gradient coil 1 can comprise a gradient coil in the Z-direction of an MRI system.

The primary conductors 3 and secondary conductors 2 are disposed along the longitudinal axis of the gradient coil 1 which can correspond to the Z-axis of an MRI system.

The position of the field maximum, or field effect maximum, of the gradient coil is influenced by the number of conductors which determine the sensitivity, the conductor cross-section as a function of current flow, and the coil thickness.

The radial position of the conductors is shown on the Y-axis of the diagram. The radially inner conductors are primary conductors 3, the radially outer conductors are secondary conductors 2. The complete gradient coil 1 is produced by mirroring at Z=0, i.e. the center of the coil, and rotating around r=0.

The position and shape of the field strength curve is determined by the arrangement of the primary and secondary conductors. By skillfully choosing this arrangement, the field effect of the Z-axis can be shifted relative to the transverse axes in order to reduce the stimulation effect of the overall coil.

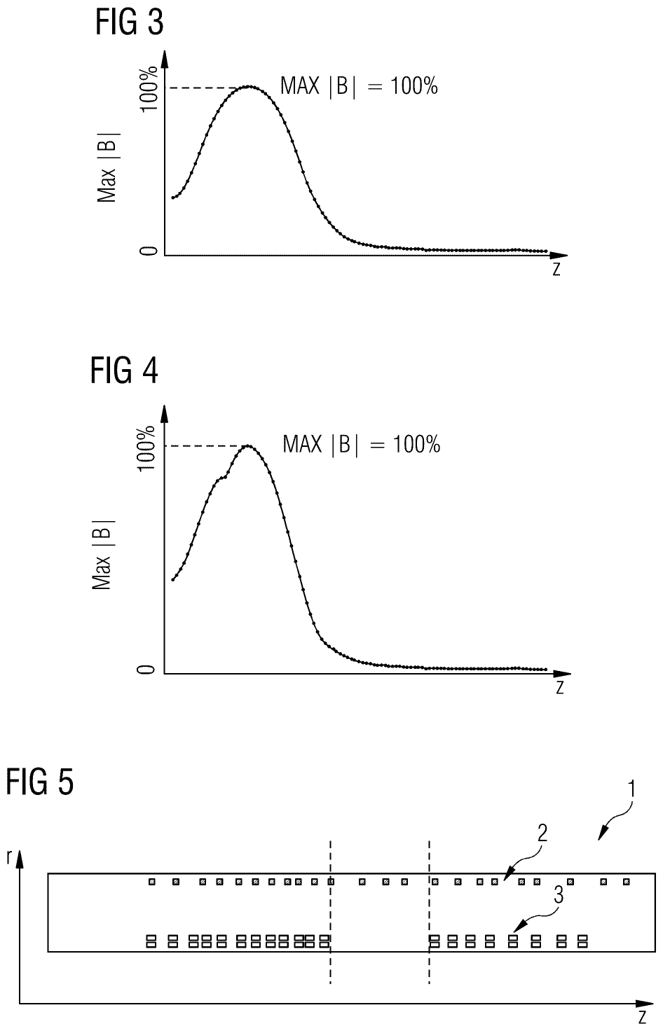

The maximum field effect of this Z-axis design on the r=20 cm cylinder is shown in the following graph, FIG. 3.

FIG. 3 illustrates the field distribution of the conventional gradient coil of FIG. 2.

As can be seen in FIG. 3, the field magnitude maxima of the gradient field are plotted on the Y-axis of the graph, and the measurement positions along the Z-axis are plotted on the X-axis of the graph. The field maximum is normalized to 100%, and the magnetic field strengths drop off on both sides along the Z-axis. The maximum field effect occurs at the center of gravity of the conductor.

FIG. 4 illustrates the resulting magnetic field strength of the superimposed gradient fields of all the gradient coils of a gradient coil arrangement using the gradient coil of FIG. 2.

The sum of the contributions of the magnetic field strengths of all three axes results in the curve shown in FIG. 4 along the Z-axis, which also has a field maximum at the spatial position of the curve in FIG. 3; this is also normalized to 100% in the diagram. The field strength drops off on both sides, wherein a secondary maximum can be seen on the side oriented toward the center of the coil, which is caused by the contributions of the coils in the X- and Y-directions.

FIG. 5 illustrates an optimized gradient coil 1, according to some exemplary embodiments.

The general arrangement of the components corresponds to FIG. 2, but the primary conductors have a different design along the longitudinal axis of the coil (Z-axis). The configuration of the gradient coil along the Z-axis can result from an optimization based on the field maxima of the X- and Y-gradient coils.

In order to reduce the maximum field effect of the gradient coil 1 without significantly affecting the gradient strength or other coil properties, no field conductors, i.e. no primary conductors 3, of the Z-gradient coil are positioned in a section along the Z-axis in the region of the Z-position of the original maximum, which corresponds to the maximum field regions of the X- and Y-gradient coils.

In an embodiment, the section along the Z-axis in which no field conductors are disposed can correspond to the position and width of one of the axis section(s) along the Z-axis of the maximum field region of one or both of the other coils in the X- and/or Y-direction, or of the combined maximum field region of the X- and Y-axes. In order to still achieve the necessary sensitivity of the coil, the other conductors are doubled, i.e. disposed in two layers in the radial direction.

This doubles the sensitivity at these positions and the field characteristics are achieved in a similar way to the original design. This targeted positioning of the conductors with simultaneous compensation of the sensitivity allows the field effect of the Z-axis and thus the stimulation effect of the overall coil to be reduced without limiting the gradient performance.

The arrangement of the secondary conductors 2 corresponds to that of FIG. 2, so that secondary conductors 2 can be disposed in the free region to shield the coil from the outside.

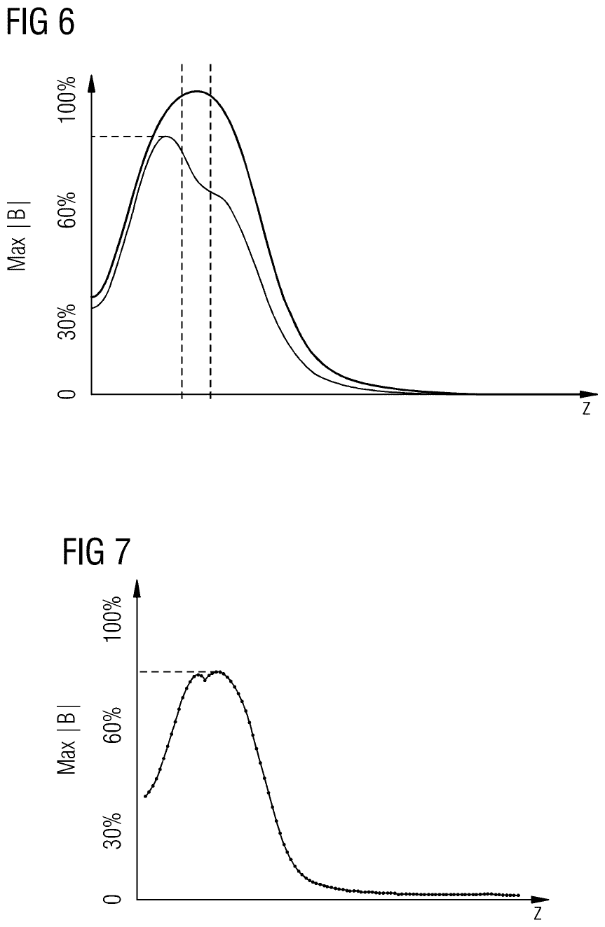

FIG. 6 shows a comparison of the field maxima of the gradient coils of FIGS. 2 and 5, according to some exemplary embodiments.

For comparison, the conventional curve of FIG. 3 is shown in addition to the reduced field strength curve of the optimized gradient coil of FIG. 5.

As can be seen from FIG. 6, there is a reduced field maximum compared to the conventional curve, i.e. a reduced field effect of the Z-gradient coil, as the position of the original maximum is left free (without Z-field conductors) in the region between the dashed lines. In an embodiment, the gap in the design of the primary conductors and the doubling of the primary conductor layers outside this gap have enabled the maximum field effect to be reduced and the position of the maximum to be shifted to the left, i.e. toward the center of the coil. This results in a slightly flattened curve in the region of the Z-field conductor gap.

FIG. 7 shows the magnetic field strength distribution of the superimposed gradient fields of the gradient coil arrangement according to FIG. 3 using the optimized gradient coil of FIG. 5, according to some exemplary embodiments.

As can be seen from FIG. 7, a person being examined is subject to a field effect which corresponds to the superimposed field strengths of the overall coil consisting of the contributions of the magnetic gradient fields in the X-, Y- and Z-axes, with a reduced maximum compared to the field strength distribution of FIG. 4.

It was therefore possible to reduce the maximum field on the r=20 cm cylinder, said reduction being reflected to the same extent in the stimulation effect of the gradient coil.

The selective positioning of the field conductors with simultaneous compensation of the sensitivity enables the field effect of the Z-axis and thus the stimulation effect of the overall coil to be reduced without limiting the gradient performance.

The arrangement of the field conductors described in the present disclosure does not optimize the stimulation effect of the individual gradient axes, i.e. does not reduce the maxima, but rather improves the interaction of the individual gradient coils in the overall coil arrangement. This is achieved by specifically shifting the position of the maximum field of the Z-axis along the Z-axis, away from the maxima of the X- and Y-axes.

Instead of arranging the Z-conductors in a single layer as is usual, a gap is provided in the region of the X/Y field maxima, and they are routed at least partially in two layers in the remaining region. This allows the position of the field maximum to be influenced without limiting the gradient performance. In principle, a three-layer arrangement of the Z-conductors would also be possible in order to optimize the field effect still further.

The stimulation optimization is therefore not aimed at the individual axes, but at the overall effect of the gradient system while maintaining the gradient strength and field linearity. This is achieved by a selective multilayer conductor arrangement, e.g. of the Z-axis, which shifts the position of the field maxima and reduces the stimulation.

Some general conclusions can therefore be drawn from the above:

A gradient coil arrangement for an MRI system can define an X-axis, a Y-axis and a Z-axis in three orthogonal spatial directions. The gradient coil arrangement can comprise respective gradient coils for each of the X-, Y-, and Z-axes designed to generate a magnetic gradient field in the direction of their respective axes. The magnetic gradient field of each axis can have a respective field maximum, i.e. a maximum field value of the magnetic gradient field, or more generally a maximum field region corresponding to a spatial region in which the field strength of the magnetic gradient field reaches at least a predetermined percentage of the maximum field strength of the magnetic gradient field. The gradient coil of the Z-axis can be configured such that its maximum field region does not spatially overlap with the maximum field region of the magnetic gradient field in the X- and/or Y-direction.

The Z-axis can correspond to the first axis in a spatial direction. The gradient coil of the Z-axis can correspond to the first gradient coil. The X- or Y-axis can correspond to the at least one second axis in a further spatial direction. In an embodiment, the Y-axis can correspond to the second axis, and the X-axis can correspond to the third axis.

The predetermined percentage can amount to any suitable value such as, for example, 50%, 60%, 70%, 75%, 80%, 85%, 90%, 95%, 96%, 97%, 98%, 99%, etc.

The field maximum and/or the maximum field region of the gradient coil of the Z-axis can be disposed at least at a spatial distance along the Z-axis with respect to the maximum field region of the gradient coils of the X- and/or Y-axis.

The spatial distance can also be defined relative to the width of the maximum field region of the X-axis, or the maximum field region of the Y-axis, or the maximum field region of the Z-axis. For example, the width could be defined according to the full width at half maximum (FWHM), or according to any suitable width, such as for instance 60% width, 70% width, 80% width, 90% width, the full width of the field maximum along the axis, etc., e.g. the Z-axis, at values corresponding to the percentage of the maximum field value.

For example, the distance may be 50%, 60%, 70%, 75%, 80%, etc. of this width. For example, the distance could also be defined in absolute terms as any suitable value, such as for instance >10 cm, >20 cm, >30 cm, >40 cm, etc.

In other words, the distance between the field maximum (i.e. maximum of the field strength distribution) of the Z-gradient coil (i.e. gradient coil of the magnetic gradient field in the Z-direction, gradient coil of the Z-axis) and the field maximum of one or both of the X- and/or Y-gradient coils, or more generally between the maximum field regions, i.e. between any points of the maximum field regions, along the Z-axis may be greater than any suitable width such as for instance 90% width, 80% width, 70% width, 60% width, 50% width, etc., of the maximum field region of the X-gradient coil (gradient coil of the magnetic gradient field in the X-direction, gradient coil of the X-axis) or of the Y-gradient coil (gradient coil of the magnetic gradient field in the Y-direction, gradient coil of the Y-axis), wherein the distance or the width is measured or defined in the Z-direction.

The spatial distance can be defined in absolute dimensions, such as for example 5 centimeters, 10 centimeters, 20 centimeters, etc., depending on the specific configuration and requirements of the system.

The distance could also be defined in relation to the total coil length, such as e.g. 10%, 20%, etc. of the total length of the coil in the Z-axis.

Due to the spatial displacement of the maximum field regions relative to each other, the sum of all the field strengths of the magnetic gradient fields generated by the gradient coils can be below a predetermined limit value.

The gradient coil of the Z-axis can be configured such that it has no field conductor, e.g. no primary conductor, in the region of the maximum field generated by the gradient coils in the X- and/or Y-direction along the Z-axis. However, is also conceivable for the X- and/or Y-gradient coil to be optimized in relation to the Z-gradient coil.

The Z-axis gradient coil (and correspondingly the X-axis or Y-axis gradient coil) can be configured such that no field conductor is disposed in particular regions along their respective axes. This absence of a field conductor in a particular region along the axis results in a displacement of the center of gravity of the conductors.

This displacement of the center of gravity affects the spatial distribution of the magnetic gradient field. By not placing a field conductor in a particular region, the magnetic flux is reduced in that region. This can be used to control and selectively place the maximum field region of the gradient coil, wherein the region without a field conductor is essentially a zone of reduced magnetic field strength.

Shifting the center of gravity of the conductors along the axis can affect the interaction between the gradient coils of the different axes. For example, the absence of a field conductor in the Z-axis gradient coil can result in its maximum field region having no spatial overlap or less spatial overlap with the maximum field region of the magnetic gradient field in the X- and/or Y-direction.

In addition, this configuration can be used to keep the total field strength of the magnetic gradient fields generated by the gradient coils below a predetermined limit. This can be particularly important for ensuring that the system operates within safe limits for medical applications such as magnetic resonance imaging (MRI).

The Z-axis gradient coil can be configured such that primary conductors in a region along the Z-axis outside the maximum field region of the X- and/or Y-axis gradient coils are multilayered, e.g. two-layered.

Regions without field conductors can be a part of the gradient coil arrangement along a particular axis (e.g. Z- or X-axis) in which no conductor element that contributes to the generation or control of the magnetic gradient field is placed.

The region without a field conductor can be disposed along the respective axis to influence the spatial distribution of the magnetic gradient field.

By excluding certain regions of the gradient coil, the region without field conductor influences the shape and strength of the generated magnetic gradient field. It can be used, for example, to avoid overlapping of the maximum field region of the gradient coils in the different spatial directions.

The region without field conductors can be achieved by a special design of the gradient coil arrangement whereby conductor materials are deliberately not used in a particular section of the coil. This can include using double-layer or multilayer designs in other regions of the coil in order to achieve the desired magnetic properties in these regions. The double-layered or multilayered regions can be directly adjacent to the region with no field conductor.

The region with no field conductor can, for example, help to keep the total field strength of the magnetic gradient fields generated by the gradient coils below a predetermined limit in order to comply with safety standards for medical applications.

The Z-axis gradient coil can be configured such that secondary conductors are disposed in a region along the Z-axis within the maximum field region of the X- and/or Y-axis gradient coils.

The gradient field of the Z-axis gradient coil can be rotationally symmetrical with respect to its longitudinal axis, e.g. the Z-axis.

The Z-axis gradient coil can be mirror-symmetrical with respect to a plane through the isocenter of the gradient coil arrangement.

The gradient coil in the Z-direction can be designed as a full-body coil.

The X-axis gradient coil can be configured such that its maximum field region does not spatially overlap with the maximum field region of the magnetic gradient field in the Y-direction.

The X-axis gradient coil can be configured such that it does not have a field conductor in the area of the maximum field region generated by the gradient coils in the Y-direction along the X-axis.

In a gradient coil arrangement, primary conductors are the main conductor elements that are responsible for generating the magnetic gradient field. They carry the main current and are therefore directly involved in generating the gradient field. The primary conductors can be disposed in different layers or positions to achieve particular magnetic properties, such as, for example, controlling the magnetic flux in particular spatial directions.

A specific area along an axis can be defined in which no primary conductors are disposed. This allows selective positioning of the maximum along the longitudinal axis of the magnetic gradient field. The primary conductors in a region along the Z-axis outside the maximum field region of the gradient coils of the X- and/or Y-axis can be multilayered, in particular two-layered.

Secondary conductors in the gradient coil arrangement have the function of screening off the magnetic field generated by the primary conductors. They do not contribute directly to the generation of the magnetic field, but influence its shape or orientation in a direction toward the outside of the coil.

In a magnetic resonance imaging (MRI) system, the Z-axis is usually defined as the axis parallel to the main magnetic field (B0 field) of the MRI device. In clinical practice, the main magnetic field is usually aligned horizontally and patients are moved into the machine along this axis. Therefore, the Z-axis is often referred to as the “longitudinal” or “vertical” axis.

The X- and Y-axes are then aligned perpendicular to the Z-axis and lie in a plane perpendicular to the main magnetic field. Together with the Z-axis, they form a Cartesian coordinate system that is used to describe the spatial position and orientation of the gradient coils and to plan and interpret the MRI scans.

The gradient coil arrangement can be designed to be oriented in the three orthogonal spatial directions X, Y and Z. Specific gradient coils are provided for each of these spatial directions. These coils are designed to generate a magnetic gradient field along their respective spatial directions.

The magnetic resonance imaging (MRI) system thus has a gradient coil arrangement comprising specific gradient coils for each axis. This arrangement includes gradient coils configured for the X-direction and designed to generate a magnetic gradient field specifically along said X-axis.

The gradient coils for the Y-direction are similarly designed. These coils are configured to generate a magnetic gradient field along the Y-axis in order to provide accurate imaging results in that specific direction.

Similarly, the gradient coil arrangement contains gradient coils that are configured for the Z-direction. These coils are designed to generate a magnetic gradient field in the Z-direction.

The gradient coil arrangement comprises one or more gradient coils, which may be referred to as “X-gradient coil(s)”. This X-gradient coil is specifically configured to generate a magnetic gradient field along the X-axis, i.e. in the X-direction. The gradient coil arrangement also comprises one or more gradient coils, which may be referred to as “Y-gradient coil(s)”, specifically designed to generate a magnetic gradient field along the Y-axis, i.e. in the Y-direction. The gradient coil arrangement further contains one or more gradient coils, which may be referred to as “Z-gradient coil(s)”, specifically designed to generate a magnetic gradient field along the Z-axis, i.e. in the Z-direction.

The gradient coil, which is aligned along the Z-axis, allows its field maximum in the Z-direction to be spatially shifted relative to at least one of the field maxima generated by the gradient coils in the X- and Y-directions.

The so-called “field maxima” can be defined as the spatial regions, in other words field maximum regions or maximum field regions, within the magnetic field in which the magnetic field strength acting on a subject under examination in the MRI system attains its highest value. These maxima are not just individual points, but spatial regions that extend in the X-, Y- and Z-directions. Each field maximum is characterized by a surrounding zone in which the magnetic field falls away to any suitable level such as for instance 90%, 80%, 70%, 60%, 50%, 40%, 30%, 20%, 10%, etc., of the maximum value.

A “field conductor”, or more specifically a “primary conductor”, is an element within the gradient coil that is capable of carrying electric current. This conductor element thereby generates a magnetic gradient field. The gradient coils, each defining the X-, Y- or Z-axis, can have one or more of these field conductors. The specific focus is on the configuration and positioning of these field conductors within the gradient coil defining the Z-axis, in order to generate an optimized magnetic gradient field.

It should be noted here that the term “primary conductors” explicitly refers to the conductor elements that directly contribute to the generation of the magnetic gradient field. These conductors are to be distinguished from “secondary conductors”, which are generally used to screen off the fields and are often positioned radially further outward.

In the context of this disclosure, the “radial direction” refers to the direction perpendicular to the axis of the coil, i.e. extending radially outward from the center of the coil. The “axial direction”, on the other hand, refers to the direction running parallel to the axis of the coil, i.e. along the longitudinal axis of the coil from one end to the other.

In the proposed configuration of the MRI system, the primary conductors used to generate the magnetic gradient field can be structured in a multilayer arrangement, e.g. in a two-layer arrangement. This means that there are a plurality of layers of primary conductors within the gradient coil, wherein “two-layer” refers to a specific embodiment in which precisely two layers of primary conductors are disposed one on top of the other.

The multilayer arrangement of primary conductors can take various forms. For example, the conductors can be disposed in successive layers along the radial direction, wherein the radial direction is defined as the direction orthogonal to the axial direction and circumference of the MRI system. This type of multilayer arrangement can help to improve the magnetic field profile and optimize the sum of all the field strengths within the field maxima.

The gradient coil, which defines the Z-axis in the proposed MRI system, can have two specific types of symmetry: axial rotational symmetry and mirror symmetry.

Axial symmetry refers to a uniformity of the structure and the generated magnetic field around the Z-axis or longitudinal axis, which can also be termed the center axis of the gradient coil. This means that, when rotated about this axis, the gradient coil's shape and properties remain the same. For instance, this symmetry can mean that the positions and/or configurations of the primary conductors within the gradient coil are disposed so as to produce a magnetic field that is evenly distributed about the Z-axis.

Mirror symmetry can refer to symmetry of the coil and generated magnetic field with respect to a plane that is perpendicular to the Z-axis and passes through the isocenter of the MRI system. The isocenter is typically the center of the volume enclosed by the gradient coil and is defined as the point at which the field strengths of the X-, Y- and Z-gradient coils attain their maximum value. With this type of symmetry, the shape and properties of the gradient coil remain the same when mirrored across this plane.

Both types of symmetry can be applicable to both the physical structure of the coil and the magnetic field generated by it and can help to optimize the magnetic field profile while minimizing the complexity of the coil arrangement.

The position of the field maximum of the gradient coil which defines the Z-axis in the proposed MRI system can be shifted in the Z-axis compared to the positions of the field maxima of the gradient coils which define the X- and Y-axes. This specific displacement defines a spatial discrepancy, wherein the field maximum of the Z-axis does not coincide with the field maxima of the X- and Y-axes, but is offset in the Z-axis.

Such a shift can be achieved not only by a complete gap in the field conductors of a coil, but also by other design optimizations. For example, further regions outside the X/Y-maxima could be designed with three or more layers, with the region itself having a reduced number of field conductors.

The maximum field region can include the field maximum. Instead of the maximum field region, a displacement can also be defined solely with the field maximum of the respective coils. The field maxima can be shifted in relation to each other, wherein they are at a predefined distance from one another. For example, this can be defined in absolute or relative terms as above for the maximum field regions using the widths of the maximum field regions.

The exact displacement can be achieved by the specific design and arrangement of the primary conductors within the Z-gradient coil. As an example, the configuration of the primary conductors can be designed to generate a magnetic field whose maximum is at a different point along the Z-axis compared to the magnetic fields generated by the gradient coils of the X- and Y-axes. This could be achieved, for example, by varying the density or arrangement of the primary conductors along the axis of the gradient coil. In an embodiment, no primary conductor can be disposed in a specific region within the gradient coil defining the Z-axis. This specific region can be located where the field maximum of the magnetic gradient field generated by this coil occurs. Due to the absence of primary conductors in this region, it can be possible to generate a specifically shaped and optimized magnetic field. It can also help to minimize unwanted magnetic field components that might otherwise arise due to the presence of primary conductors in this region.

The exact size and location of this region without primary conductors within the gradient coil can vary depending on the specific requirements of the MRI system, the characteristics of the other gradient coils, and the aims of magnetic field optimization. However, it could typically be a region having a width corresponding to the width at which the magnetic field strength of (at least) one other gradient coil in a different spatial direction attains at least a predetermined percentage of its maximum value, for example 90%, 80%, 70%, 60%, 50%, etc., or any other suitable predetermined percentage.

Although the disclosure has been illustrated and described with reference to particular preferred exemplary embodiments, equivalents and modifications will be made by those skilled in the art after reading and understanding the description. The present disclosure encompasses all such equivalents and modifications and is limited only by the scope of the appended claims. Independent of the grammatical term usage, individuals with male, female or other gender identities are included within the term.

The various components described herein may be referred to as “units.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units, as applicable and relevant, may alternatively be referred to herein as “circuitry,” “controllers,” “processors,” or “processing circuitry,” or alternatively as noted herein.

What is claimed is:

1. A gradient coil arrangement for a magnetic resonance imaging (MRI) system, the gradient coil arrangement comprising a first axis and at least one second axis in different spatial directions than one another, the gradient coil arrangement comprising:
at least one gradient coil for each of the different spatial directions, each gradient coil being configured to generate a magnetic gradient field in a direction of a respective axis,
wherein the gradient coil for each of the different spatial directions is configured to generate a magnetic gradient field having a respective maximum field region corresponding to a spatial region in which a field strength attains at least a predetermined percentage of a maximum field strength of the respective magnetic gradient field, and
wherein a gradient coil of the first axis is configured such that a spatial overlap of a maximum field region of the magnetic gradient field in a direction of the at least one second axis is less than a predetermined limit value.

2. The gradient coil arrangement as claimed in claim 1, wherein the predetermined percentage comprises 90%.

3. The gradient coil arrangement as claimed in claim 1, wherein the predetermined limit value is selected such that the spatial overlap is less than 10% of the maximum field region of the magnetic gradient field in the direction of the first axis or the at least one second axis.

4. The gradient coil arrangement as claimed in claim 1, wherein the gradient coil of the first axis comprises a whole-body coil.

5. The gradient coil arrangement as claimed in claim 1, wherein the maximum field region of the gradient coil of the first axis is disposed at a spatial distance without overlap along the first axis from the maximum field region of the gradient coils of the at least one second axis.

6. The gradient coil arrangement as claimed in claim 1, wherein spatial displacement of the maximum field regions relative to one another result in a sum of field strengths of the magnetic gradient fields generated by the gradient coils being below the predetermined limit value.

7. The gradient coil arrangement as claimed in claim 1, wherein the gradient coil of the first axis is configured to have a reduced conductor density in a section of the first axis corresponding to the maximum field region of the at least one second axis, and
wherein the reduced conductor density is at most 10% of a conductor density of an equal-width adjacent section of the gradient coil of the first axis.

8. The gradient coil arrangement as claimed in claim 1, wherein the gradient coil of the first axis is configured to have no field conductors in a section of the first axis corresponding to the maximum field region of the gradient coil of the at least one second axis.

9. The gradient coil arrangement as claimed in claim 1, wherein the gradient coil of the first axis is configured such that primary conductors are multilayered in a region outside a section along the first axis corresponding to the maximum field region of the at least one second axis.

10. The gradient coil arrangement as claimed in claim 1,
wherein the first axis comprises a Z-axis of the MRI system, which corresponds to a longitudinal axis of the MRI system corresponding to an orientation of an examination subject, and
wherein the at least one second axis comprises an X-axis or a Y-axis of the MRI system.

11. The gradient coil arrangement as claimed in claim 1, wherein:
the at least one second axis comprises a second axis and a third axis, the gradient coil arrangement defining the first axis, the second axis, and the third axis,
the first axis comprises a Z-axis of the MRI system, which corresponds to a longitudinal axis of the MRI system corresponding to an orientation of an examination subject,
the second axis comprises a Y-axis of the MRI system, and
the third axis comprises an X-axis of the MRI system.

12. The gradient coil arrangement as claimed in claim 11, wherein the gradient coil of the Z-axis is configured such that a spatial overlap of maximum field region with a combined maximum field region corresponding to a combination of the magnetic gradient fields in the Y-axis and the X-axis directions is less than the predetermined limit value.

13. The gradient coil arrangement as claimed in claim 1, wherein the gradient field of the gradient coil of the first axis is rotationally symmetrical with respect to its longitudinal axis.

14. The gradient coil arrangement as claimed in claim 13, wherein the longitudinal axis comprises a Z-axis of the MRI system.

15. The gradient coil arrangement as claimed in claim 1, wherein the gradient coil of the first axis is symmetrical with respect to a plane through an isocenter of the gradient coil arrangement.

16. A magnetic resonance imaging (MRI) system, comprising:
a main magnet; and
a gradient coil arrangement including a first axis and at least one second axis in different spatial directions than one another, the gradient coil arrangement comprising at least one gradient coil for each of the different spatial directions, each gradient coil being configured to generate a magnetic gradient field in a direction of a respective axis,
wherein the gradient coil for each of the different spatial directions is configured to generate a magnetic gradient field having a respective maximum field region corresponding to a spatial region in which a field strength attains at least a predetermined percentage of a maximum field strength of the respective magnetic gradient field, and
wherein a gradient coil of the first axis is configured such that a spatial overlap of a maximum field region of the magnetic gradient field in a direction of the at least one second axis is less than a predetermined limit value.
